(19) United States
(12) Patent Application Publication
(10) Pub. No.: US 2015/0284851 A1
(43) Pub. Date: Oct. 8, 2015

(54) Systems and Methods to Control Sources of Atomic Species in a Deposition Process

(71) Applicant: BATTELLE MEMORIAL INSTITUTE, Richland, WA (US)

(72) Inventors: Yingge Du, Richland, WA (US); Scott A. Chambers, Kennewick, WA (US); Timothy C. Droubay, Richland, WA (US); Andrey V. Liyu, Richland, WA (US)

(73) Assignee: BATTELLE MEMORIAL INSTITUTE, Richland, WA (US)

(21) Appl. No.: 14/246,477

(22) Filed: Apr. 7, 2014

(51) Int. Cl. C23C 16/52

(52) U.S. Cl. CPC C23C 16/52

(57) ABSTRACT

Systems and methods as well as components and techniques can exhibit stable and accurate control of a deposition process by monitoring background-corrected deposition rates of an atomic species via atomic absorption (AA) spectroscopy. The systems and methods have high sensitivity and resolution in addition to extremely effective background correction and baseline drift removal, achieved in part by basing the background correction and baseline drift removal on analysis of resonant and non-resonant AA lines. The systems and methods can result in surprisingly short warm-up times and can drastically reduce the noise coming from the instruments and the surrounding environment.

### STATEMENT REGARDING FEDERALLY SPONSORED RESEARCH OR DEVELOPMENT

This invention was made with Government support under Contract DE-AC0576RLO1830 awarded by the U.S. Department of Energy. The Government has certain rights in the invention.

### BACKGROUND

Atomic absorption (AA) spectroscopy can be used in procedures for the quantitative determination of chemical elements. Optical flux sensors based on AA principles have been studied and employed to monitor the atom flux during thin film deposition processes. However, traditional AA-based sensors for flux measurement rarely provide satisfactory detection and control, in part, because of baseline drift and background interference. Many of the existing designs rely on a low-resolution monochromator or a band pass filter with a wide band pass (5-10 nm window) to select the wavelength of interest, and a photomultiplier tube (PMT) or a charge-coupled device (CCD) for light detection. The disadvantages of using a wide slit width are low sensitivity and non-linearities in the calibration curve. In addition, instabilities in the device components (e.g., light sources, detectors, optics, etc.) can result in non-negligible baseline drift over time, even when there is no atom flux in the optical path. Instabilities are particularly troublesome during the early phases of operation, especially for hollow cathode lamps working in constant-current mode. Furthermore, unintentional coating on the view ports of a deposition chamber can change the transmission of the light along the sampling optical path. Slight optical misalignment or motion in optical guides and/or fiber optic cables can produce spurious changes in light intensity. Frequent re-calibrations of the baseline while blocking the atom beam can circumvent baseline stability issues, but such steps can significantly interfere with thin-film deposition processes. In view of the above, the need exists for a new and improved method of controlling deposition processes based on AA sensors with background-corrected deposition rate and atomic densities obtained therefrom.

### SUMMARY

This document describes systems and methods to measure and control atom beam fluxes used in deposition processes. The systems and methods are based on atomic absorption (AA) spectroscopy, which constitutes a highly sensitive method of detecting dilute atomic species in some volume containing a gaseous phase. Most commonly, the volume is within a deposition chamber. Examples of deposition processes can include, but are not limited to molecular beam epitaxy, physical vapor deposition, pulsed laser deposition, and sputtering. Embodiments described herein can provide accurate deposition rates, which can be converted to atomic densities, after highly effective background correction and baseline drift removal. Additionally, the described embodiments have some unexpected advantages, including shorter warm-up times and robustness against physical disturbances such as minor impacts and/or vibration to system components.

Systems for controlling deposition processes can be based on monitoring background-corrected deposition rates of an atomic species via atomic absorption (AA) spectroscopy. The systems can include a source that generates the atomic species in a volume at some rate of output, and a light source configured to emit light having at least one wavelength that is at least partially absorbed by the atomic species. Optical guides can be configured to direct a portion of the light as a reference beam to a spectrometer. Another portion of the light can be directed as an AA sampling beam through the volume containing the atomic species and then to the spectrometer. The spectrometer can be configured to spatially disperse onto a two-dimensional detector the reference beam and the AA sampling beam that emerges from the volume in order to yield reference spectral data and sampling spectral data, respectively. A computational device is configured to receive the sampling and reference spectral data from the detector and is programmed to quantify a non-resonant or weakly resonant absorbance value (A_{NR}) and a resonant absorbance value (A_{R}) from the sampling and reference spectral data. The computational device then corrects the A_{R} value according to the A_{NR} value measured at common moments in time, thereby yielding background-corrected absorbance values, and determines background-corrected deposition rates of the atomic species based on a correlation between the background-corrected absorbance values and the actual deposition rates as independently measured. Once the AA sensor is calibrated, the controller can regulate the rate of output of the atomic species according to the background-corrected deposition rates, wherein the controller is connected to the computational device in a feedback loop configuration.

In one embodiment, the source of the atomic species comprises an evaporator. Examples of an evaporator can include, but are not limited to an electron-beam evaporator or an effusion cell evaporator connected to a power source. The controller can comprise a control loop which is connected to the power source to regulate the power provided to the evaporator.

In preferred embodiments, the light sources can include, but are not limited to hollow cathode lamps (HCL). A separate HCL can be used for each unique atomic species monitored by the embodiments of the present invention. Preferably, each HCL has a cathode comprising the atomic species that is being sampled in the volume so that the HCL will emit light, which is at least partially absorbed by the atomic species in the volume. Alternatively, the light source can be an electrodeless discharge lamp.

Examples of optical guides can include components such as mirrors, beam splitters, lenses, apertures, prisms, fiber optics, and other optical instruments for manipulating electromagnetic radiation. Combinations of optical guide components can be used to direct light from the light source according to embodiments of the present invention. Preferably, the optical guides include fiber optics. In one embodiment, the optical guides comprise optical fiber bundles. The arrangement of the fibers in each bundle can be linear at the output end that is relatively proximal to the spectrometer. The linear arrangement of fibers can, for example, eliminate the need for a slit at the entrance of the spectrometer without sacrificing a portion of the light collected at the input end of the fiber optic bundle. Preferably, the cross-sectional size of the fiber optics is small enough to maintain the resolution achieved by the light source, spectrometer, and detector such that the absorption lines in the spectral data are not unnecessarily obscured. In one embodiment, the diameter of each fiber is less than or equal to 500 micrometers. In another, each fiber is less than or equal to 200 micrometers. Preferably, the A_{R} value and the A_{NR} value have a wavelength separation of 0.5-30 nm.

One example of a two-dimensional detector includes, but is not limited to, a two-dimensional charge-coupled device (CCD) camera. In preferred embodiments, the detector has an area that is large enough for the reference and sampling spectral data to impinge on first and second regions.

Another embodiment encompasses a system for controlling a deposition process by monitoring background-corrected deposition rates of an atomic species via atomic absorption (AA) spectroscopy. The system comprises an evaporator providing the atomic species into a deposition chamber at a rate of output. A HCL is configured to emit light having at least one wavelength that is at least partially absorbed by the atomic species. One or more optical fiber bundles is configured to direct a portion of the light as a reference beam to a spectrometer and another portion of the light as an AA sampling beam through the deposition chamber and then to the spectrometer, the optical fiber bundle having a linear arrangement of optical fibers at an output end that is proximal to the spectrometer. The spectrometer is configured to spatially disperse according to wavelength the AA sampling beam emerging from the deposition chamber and the reference beam onto a two-dimensional detector. The two-dimensional detector comprises a first region and a second region. The AA sampling beam and reference beam can be directed by optical guides to impinge the first and second regions, thereby yielding sampling spectral data and reference spectral data, respectively. A computational device is configured to receive the sampling spectral data and the reference spectral data from the detector. The computation device is programmed to quantify a non-resonant or weakly resonant absorbance value (A_{NR}) and a resonant absorbance value (A_{R}) from the sampling and reference spectral data, to correct the A_{R} value according to the A_{NR} value at common moments in time, thereby yielding background-corrected absorbance values, and to determine background-corrected deposition rates of the atomic species based on a correlation between the background-corrected absorbance values and the actual rates of output.

Yet another embodiment encompasses methods for controlling a deposition process by monitoring background-corrected deposition rates of an atomic species via atomic absorption (AA) spectroscopy. The method comprises emitting from a light source light having at least one wavelength that is strongly absorbed by the atomic species and directing a portion of the light as a reference beam to a spectrometer and another portion of the light as an AA sampling beam through a volume containing the atomic species and then to the spectrometer. The method further comprises spatial dispersion according to wavelength the AA sampling beam emerging from the volume and the reference beam onto a two-dimensional detector, thereby yielding sampling spectral data and reference spectral data, respectively. A non-resonant or weakly resonant absorbance value (A_{NR}) and a resonant absorbance value (A_{R}) are quantified from the sampling and reference spectral data, respectively. The A_{R} values are corrected according to the A_{NR} values at common moments in time, thereby yielding background-corrected absorbance values. Background-corrected deposition rates of the atomic species are determined based on a correlation between a rate of output of the atomic species and the background-corrected absorbance values.

In some embodiments, the method further comprises providing the atomic species by heating an evaporator via an electron-beam evaporator or an effusion cell evaporator connected to a power source and regulating the power source using a controller connected to the power source.

In preferred embodiments, the method comprises directing the AA sampling beam from the spectrometer to a first region of the two-dimensional detector and directing the reference beam from the spectrometer to a second region of the two-dimensional detector.

The purpose of the foregoing summary is to enable the United States Patent and Trademark Office and the public generally, especially the scientists, engineers, and practitioners in the art who are not familiar with patent or legal terms or phraseology, to determine quickly from a cursory inspection the nature and essence of the technical disclosure of the application. The summary is neither intended to define the invention of the application, which is measured by the claims, nor is it intended to be limiting as to the scope of the invention in any way.

Various advantages and novel features of the present invention are described herein and will become further readily apparent to those skilled in this art from the following detailed description. In the preceding and following descriptions, the various embodiments, including the preferred embodiments, have been shown and described. Included herein is a description of the best mode contemplated for carrying out the invention. As will be realized, the invention is capable of modification in various respects without departing from the invention. Accordingly, the drawings and description of the preferred embodiments set forth hereafter are to be regarded as illustrative in nature, and not as restrictive.

### DESCRIPTION OF DRAWINGS

Embodiments of the invention are described below with reference to the following accompanying drawings.

FIG. 1 includes a schematic drawing of a system to control a source of atomic species in a deposition process according to one embodiment of the present invention.

FIGS. 2A-2B include schematic diagrams for (A) a fiber optic bundle having a linear arrangement of fibers, and (B) spectral data according to embodiments of the present invention.

FIGS. 3A-3C include (A) an image from a 2-D detector of the emission spectra from a Cr HCL according to one embodiment of the present invention, (B) Cr absorbance measured with a conventional double-beam AA configuration (PRIOR ART), and (C) Cr absorbance measured with a self-corrected double-beam configuration according to embodiments of the present invention.

FIGS. 4A-4B include (A) an experimental trace for the self-corrected double-beam configuration control of an electron beam evaporation of Cr and (B) a Cr flux measurement by a QCO on the side of a sample manipulator during the last 3000 seconds of the data shown in FIG. 4A.

FIGS. 5A-5B include (A) RHEED patterns for an α-Al₂O₃(0001) substrate and an α-Cr₂O₃(0001) film along different low-symmetry directions and (B) RHEED intensity oscillations for the specular beam in the [101 bar0] direction.

### DETAILED DESCRIPTION

The following description includes the preferred best mode of one embodiment of the present invention. It will be clear from this description of the invention that the invention is not limited to these illustrated embodiments but that the invention also includes a variety of modifications and embodiments thereto. Therefore the present description should be seen as illustrative and not limiting. While the invention is susceptible of various modifications and alternative constructions, it should be understood, that there is no intention to limit the invention to the specific form disclosed, but, on the contrary, the invention is to cover all modifications, alternative constructions, and equivalents falling within the spirit and scope of the invention as defined in the claims.

Disclosed are systems and methods as well as components and techniques thereof for controlling aspects of a deposition process by monitoring background-corrected deposition rates of an atomic species via AA spectroscopy. The systems and methods have high sensitivity and resolution in addition to extremely effective background correction and baseline drift removal. The systems disclosed herein can require shorter warm-up times and can reduce the noise coming from the surrounding environment.

The following explanations of terms and abbreviations are provided to better describe the present disclosure and to guide those of ordinary skill in the art in the practice of the present disclosure. As used herein, “comprising” means “including” and the singular forms “a” or “an” or “the” include plural references unless the context clearly dictates otherwise. The term “or” refers to a single element of stated alternative elements or a combination of two or more elements, unless the context clearly indicates otherwise.

Unless explained otherwise, all technical and scientific terms used herein have the same meaning as commonly understood to one of ordinary skill in the art to which this disclosure belongs. Although methods and materials similar or equivalent to those described herein can be used in the practice or testing of the present disclosure, suitable methods and materials are described below. The materials, methods, and examples are illustrative only and not intended to be limiting. Other features of the disclosure are apparent from the following detailed description and the claims.

Unless otherwise indicated, all numbers expressing quantities of ingredients, properties such as molecular weight, percentages, ratios and so forth, as used in the specification and claims are to be understood as being modified by the term “about.” Unless otherwise indicated, non-numerical properties used in the specification or claims are to be understood as being modified by the term “substantially,” meaning to a great extent or degree, as within inherent measurement uncertainties. Accordingly, unless otherwise indicated, implicitly or explicitly, the numerical parameters and/or non-numerical properties set forth are approximations that may depend on the desired properties sought, limits of detection under standard test conditions/methods, limitations of the processing method, and/or the nature of the parameter or property. When directly and explicitly distinguishing embodiments from discussed prior art, the embodiment numbers are not approximates unless the word “about” is recited.

To facilitate review of the various embodiments of the disclosure, explanations of specific terms are provided herein.

A deposition process as used herein refers to a variety of methods used to deposit thin films by the condensation of a vaporized form of the desired film material onto various workpiece surfaces. Typically, the deposition occurs under vacuum. Examples of deposition processes can include, but are not limited to molecular beam epitaxy, physical vapor deposition, pulsed laser deposition, and sputtering.

An atomic species, as used herein, can refer to a particular chemical element in an elemental, atomic, intermediate, or excited form. Typically, it refers to the atomic, unexcited form of an element. The source of the atomic species might or might not exist in the same form as the atomic species. For example, a source can comprise a solid, elemental metal. However, the atomic species provided by the source can comprise an atom of the element, which atom is not a metal.

Atomic absorption spectroscopy, as used herein, can refer to the spectroanalytical procedure for the quantitative determination of chemical elements using the absorption of optical radiation, or light, by free atoms in the gaseous state.

The rate of output of atomic species from the source can be described quantitatively using various measures including, but not limited, to deposition rate (thickness of material deposited by the deposition process per unit time), density of atomic species (quantity per volume containing a gaseous phase) measured at moments in time, and flux (rate of flow per unit area). These terms can be converted one to another and can be used interchangeably.

An absorbance value, as used herein, is based on light intensities with and without the presence of the atomic species. Particular wavelengths are more strongly absorbed by an atomic species. Absorbance values at such wavelengths can be referred to as “absorbance lines” given the resemblance based on AA spectra at high resolutions.

Background correction, as used herein, can refer to manipulation of data acquired from AA spectroscopy to remove contributions to the absorption values that are not directly resulting from the atomic species (i.e., background absorption). Background absorption can result from optical guides, instruments, overlapping molecular absorption, accumulation of matter on optical windows, drift of the baseline signal, and other apparent sources of absorption.

A spectrometer, as used herein, can refer to an instrument used to measure properties of light over a specific portion of the electromagnetic spectrum, commonly used in spectroscopic analysis to identify materials. The independent variable is usually the wavelength of the light or a unit directly proportional to the photon energy, such as wavenumber or electron volts, which has a reciprocal relationship to wavelength. A spectrometer is commonly used in spectroscopy for producing spectral lines to measure their wavelengths and intensities. While the term spectrometer can, at times, encompass a detector, as used herein, the detector is often described as a distinct component or element for the sake of clarity.

A computational device, as used herein, can refer to a computing system that includes processing circuitry, storage circuitry, and a communications interface. Other embodiments are possible including more, less and/or alternative components such as a user interface and/or user input devices. In one embodiment, processing circuitry is arranged to process data, control data access and storage, issue commands, and control other desired operations. Processing circuitry may implement the operations of the detector, spectrometer, source of atomic species, controller, and more. For example, the processing circuitry may implement control operations on a source of the atomic species based on spectral data received from the detector and on calculations performed by the processing circuitry. Processing circuitry may comprise circuitry configured to implement desired programming provided by appropriate computer-readable storage media in at least one embodiment. For example, the processing circuitry may be implemented as one or more processor(s) and/or other structure configured to execute executable instructions including, for example, software and/or firmware instructions. Other exemplary embodiments of processing circuitry include hardware logic, PGA, FPGA, ASIC, state machines, and/or other structures alone or in combination with one or more processor(s). These examples of processing circuitry are for illustration and other configurations are possible. Storage circuitry is configured to store programming such as executable code or instructions (e.g., software and/or firmware), electronic data, databases, data structures, or other digital information and may include computer-readable storage media. At least some embodiments or aspects described herein may be implemented using programming stored within one or more computer-readable storage medium of storage circuitry and configured to control appropriate processing circuitry. The computer-readable storage medium may be embodied in one or more articles of manufacture which can contain, store, or maintain programming, data and/or digital information for use by or in connection with an instruction execution system including processing circuitry in the exemplary embodiment. For example, exemplary computer-readable storage media may be non-transitory and include any one of physical media such as electronic, magnetic, optical, electromagnetic, infrared or semiconductor media. Some more specific examples of computer-readable storage media include, but are not limited to, a portable magnetic computer diskette, such as a floppy diskette, a zip disk, a hard drive, random access memory, read only memory, flash memory, cache memory, and/or other configurations capable of storing programming, data, or other digital information. Communications interface is arranged to implement communications of the computational device with respect to external devices including, but not limited to, the detector, spectrometer, controller, source of atomic species, and light source. Communications interface may be implemented as a network interface card, serial or parallel connection, USB port, Firewire interface, flash memory interface, or any other suitable arrangement for implementing communications.

A controller operated in a feedback and/or feedforward loop configuration. In one embodiment, the controller is part of a closed-loop system using feedback to control states or outputs of a dynamical system. It can encompass the information path in a control system: process inputs have an effect on the process outputs, which is measured with sensors and processed by the controller; the result (the control signal) is “fed back” as input to the process, closing the loop.

Optical flux sensors based on the atomic absorption (AA) principle can monitor the flux of an atomic species during thin film growth. By passing a light beam having at least some wavelengths matched in energy to absorption energies of the element of interest, one can detect the light intensity attenuation resulting from resonant atomic absorption. The attenuation is a function of the atom density within the irradiated volume and can be calibrated to determine the deposition rate of the atomic species on a substrate. AA flux sensors can be element specific and non-invasive with respect to the deposition process. Conventional AA-based flux sensor designs use a monochromator or bandpass filter with a wide slit or bandpass (5-10 nm window) to select the wavelength of interest, and a photomultiplier tube (PMT) or a charge coupled device (CCD) for light detection. Wide slits or wide bandpass widths can result in poor sensitivity due to the inclusion of both resonant and non-resonant lines in the detected signal, and to the presence of non-linearities in the calibration curve. Conventional AA-based flux sensor designs utilize a normalization scheme in which the absorption is measured in relation to the total output of the light source, which is typically a HCL. However, in these conventional designs, instabilities in the HCL output can result in non-negligible baseline drift over time even when there is no atom flux in the optical path, particularly during the first hour of operation in constant-current mode. Additional sources of noise or baseline drift in conventional designs include unintentional coating or other real-time changes to hardware in the optical path that change the transmission. Similarly, slight optical misalignment or motion in the individual optical components can produce spurious changes in light intensity, which can negatively affect the outcome.

A double-beam setup can help compensate for long-term changes in the intensity of the light source and in the sensitivity of the detector. Some conventional double-beam designs utilize frequent re-calibrations of the baseline while blocking the atom beam to circumvent baseline stability issues, but such steps can be difficult to implement and can interfere with thin-film deposition processes, especially automated ones. In one of the first commercially available AA-based flux sensors, a double-beam optical configuration was combined with the common optical path for automatic correction of transmission (COPACT) geometry, in which a xenon flash lamp was used as a reference. This scheme was shown to improve long-term stability in the baseline, enabling continuous detection, although a manual re-zero is typically required before each experiment. The use of a xenon flash lamp, however, also introduces another potential source of instability, and requires a portion of the detection time, thereby lowering the overall signal-to-noise ratio and measurement frequency.

To improve the state of the art in the detection and control of atomic species during deposition processes, the described invention discloses systems and methods encompassing superior background correction and baseline drift removal to obtain highly accurate background-corrected deposition rates of atomic species. The background-corrected deposition rates are used to control the rate of output of the atomic species to achieve stable and reproducible depositions.

The disclosed systems and methods combine a high-resolution spectrometer and a high-precision two-dimensional detector in a double-beam configuration to detect a non-resonant or weakly resonant emission line and a resonant analytical line for accurate flux sensing and control when operated in deposition processes. The use of a high-resolution spectrometer enables detection of the analytical peak of interest, resulting in optimal signal response and enhanced signal-to-noise ratio. The result is monitoring of atomic species deposition rates having superior background correction and baseline drift removal, both of which are critical for long-term stability. Embodiments disclosed herein also offer other unique advantages, including a reduced system warm-up time and considerably less sensitivity to external disturbances, such as slight disturbance to the optical guides during measurement.

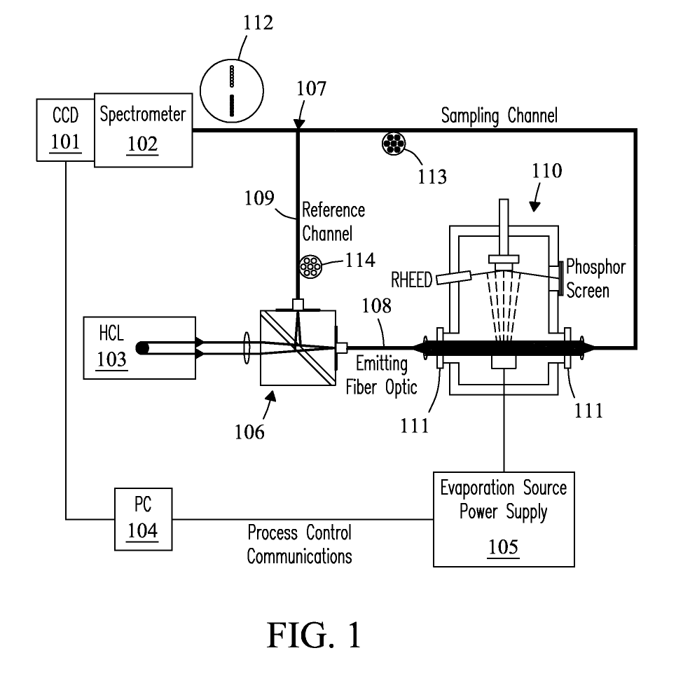

Depicted in FIG. 1 is an embodiment of a system for controlling a source of an atomic species during a deposition process. A light source 103 comprises a HCL operated in constant-current mode. The optical guides include a beam splitter 106 and fiber optic bundles 107. In the instant embodiment, a 70/30 optical beam splitter 106 is used to separate the HCL light into two beams, defined as the AA sampling beam 108 and the reference beam 109, respectively. The beam with higher intensity is focused by a lens onto a multimode (1 mm core diameter) optical fiber (denoted as emitting fiber optic) to direct the AA sampling beam to a deposition apparatus 110, which is depicted as a MBE chamber in FIG. 1. Components for determining absorbance values are coupled to the MBE chamber through two viewports 111 that provide non-invasive monitoring and control. The viewports can comprise, for example, fused silica. In the instant example, the AA sampling beam, after passing through a collimator coupled with the viewport, passes through the MBE chamber, and is collected by a sampling leg of a UV-VIS bifurcated optical fiber bundle 107.

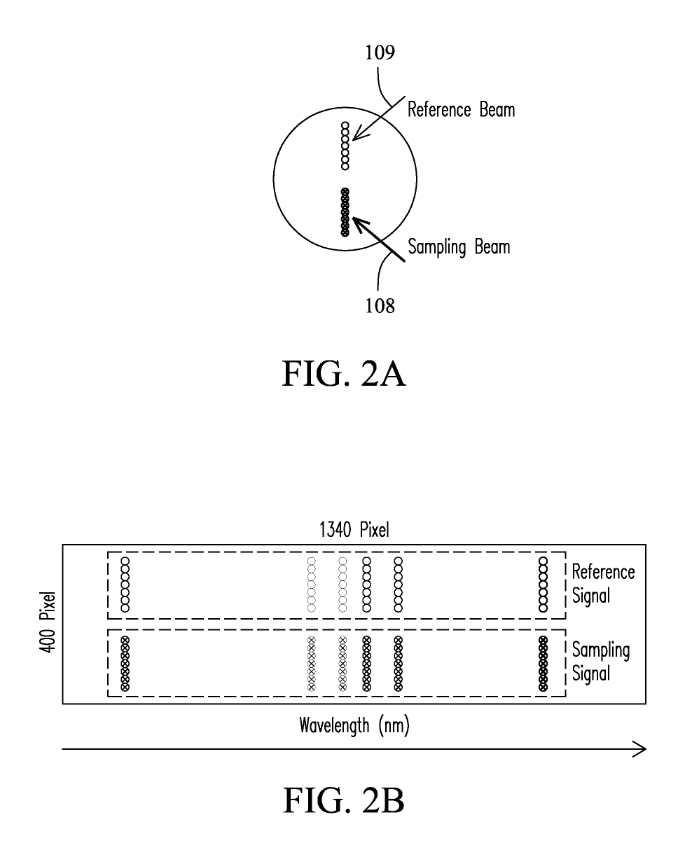

The reference beam is collected by the reference leg of the same bifurcated fiber bundle 107. Each of the reference and sampling legs included 7 subunits of 200 μm diameter optical fibers in a “1+6” configuration on a SMA-905 connector (cross sections are shown in FIGS. 1, 114 and 113, respectively). The bifurcated fiber bundle carries the sampling and reference beams in separate sub-bundles and runs them into the spectrometer with a 10 mm ferrule on the common end in a “7+7” vertical configuration 112, as shown with greater detail in FIG. 2A.

The spectrometer 102 disperses the two beams onto a two dimensional detector 101. In the instant example, the two-dimensional detector comprised a thermoelectrically cooled, high sensitivity 2-D CCD camera (PI Acton PIXIS 400F®, 1340×400, 20×20 μm size). Preferably, the optical fiber arrays corresponding to the reference and sampling legs are each arranged such that the optical fibers in the fiber bundle at the end nearer the entrance to the spectrometer are vertically aligned 112, as described above and elsewhere herein. The vertical arrangement of the fibers can eliminate the need for an entrance aperture, thereby maximizing the signal provided to the spectrometer and detector. In other arrangements, an entrance slit can be preferable. The resulting image on the CCD is spatially resolved and can be separated into two regions: the sampling signal (inside the dashed rectangle in FIG. 2B) and the reference signal (inside the dotted rectangle in FIG. 2B). The sampling and reference spectra are dispersed by wavelength along the 1340 pixels of the CCD camera, using a standard grating (1200 G/mm with 300 nm blaze wavelength), along with a motorized mirror drive. Multiple emission lines in the pm width range can be observed on the CCD as isolated dot arrays with the resolution determined by the size of the effective entrance slit. Given the vertical fiber arrangement of the instant example, the effective entrance slit is equivalent to the width of the optical fibers, in this case, 200 μm. The outputs of the digital CCD camera are read in imaging mode and then vertically summed within the sampling and reference regions to yield two spectra. The intensity from one irradiation line is then calculated by horizontally integrating over the designated pixels.

At very low flux and under monochromatic radiation, the absorption of the resonant lines follows the Beer-Lambert law as shown in Equation 1.

$$A ( hv , t ) = {log}_{10} ( \frac{{I}_{i n}}{{I}_{out}} ) ∝ n ( t ) Lk ( hv ) \qquad Eqn . 1$$

Here A is the absorbance, h is the Plank's constant, vis the light frequency, t is time, Iᵢₙ is the light intensity incident on the sampled volume containing the atomic species, Iₒᵤₜ is the light intensity after passing through the atomic species, n is atomic density therein, L is the length of the absorbing path, and k is absorption coefficient. In a double beam configuration, Iₒᵤₜ is directly measured as the sampling intensity, Iₛₐₘₚₗₑ. Iᵢₙ is the sampling light intensity before entering the sampling volume and is calculated by the following.

$${I}_{i n} ( hv , t ) = {I}_{ref} ( hv , t ) * ( \frac{{I}_{{sample}_{o}}}{{I}_{{ref}_{o}}} ) \qquad Eqn . 2$$

Here I_{ref} is the reference channel intensity, I_{ref}, and Iₛₐₘₚₗₑₛ are reference and sampling intensities measured at a specific time, typically right after the system warm-up, when the atomic flux is zero. Combining Equations 1 and 2 yields the following.

$$A ( hv , t ) = {log}_{10} ( c * \frac{{I}_{ref}}{{I}_{sample}} ) \qquad Eqn . 3$$

Here c=Iₛₐₘₚₗₑ/I_{ref}_{ₒ}, which will be refreshed whenever a “Re-zero” action is taken. A re-zero, as used herein can refer to an action to set A to 0 by replacing previously stored values of Iₛₐₘₚₗₑ_{ₒ} and I_{ref}_{ₒ} with current readings. One assumption implicit in Equation 2 is that the ratio of Iₛₐₘₚₗₑ_{ₒ} and I_{ref}_{ₒ}, determined by the coefficients of the beam splitter and optical path, does not vary with wavelength or time. However, during the warm-up phase, the beam splitter is under HCL illumination in ambient environment, and thus temperature changes may lead to mechanical misalignment or initial changes in reflection and transmission coefficient until it reaches equilibrium. In addition, for a HCL in the warm-up phase, the light intensity as well as the plasma position changes inside the HCL. The latter only affects the optical alignment between the HCL and beam splitter, and thus cannot be mitigated by the use of a Xenon flash lamp or deuterium lamp as a reference. As a result, a warm-up period of ˜1 hr is routinely required to allow for the HCL and beam splitter to reach thermal equilibrium.

According to embodiments described herein, a non-resonant or weakly resonant line from the light source is used for baseline drift removal. In preferred deposition processes, the atomic species emitted from the source into the volume are in their ground electronic states, photons with energies equal to the energy difference between particular excited states and the ground state can be absorbed by the atomic species. As a result, emission lines associated with transitions involving two excited states, and inert gas emission lines, generated in the HCL will not be absorbed. One would expect that the absorbance should be zero throughout the experiment for all non-resonant lines. However, in an actual experimental configuration, the absorbance of the non-resonant line (A_{NR}) tends to slowly and monotonically increase and decrease, or “drift” over time, in a way that is proportional to the baseline drift. Thus, A_{NR} is a direct measure of baseline drift and provides a way for real-time correction. The true absorbance after correction is given by A=A_{R}−A_{NR} (A_{R} is the absorbance of a resonant line). In preferred embodiments, the non-resonant and resonant lines originate from the same light source and go through the same optical path. Accordingly, any background absorption associated with viewport coatings or optical misalignment, will affect both A_{R} and A_{NR} and thus can also be automatically removed.

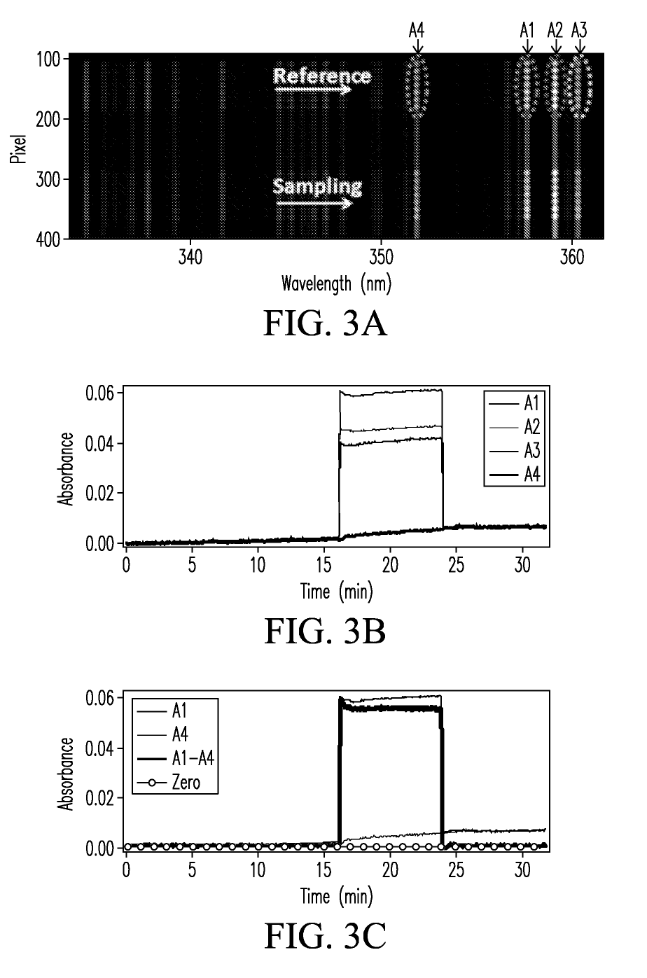

FIG. 3A shows the emission spectra from a chromium HCL collected on a 2-D CCD after the HCL has been turned on for 20 min. In the spectra, wavelengths are horizontally dispersed on the CCD between 334 nm and 362 nm. The sampling and reference beams appear as a series of vertically aligned dots according to the linear arrangement of fibers in the sampling and reference legs of the optical fiber bundle. There are three strong resonant lines at 357.9, 359.3, and 360.5 nm, labeled as A1, A2, and A3 respectively. In addition, there is a non-resonant line at 352.0 nm, labeled A4. FIG. 3B shows the absorbance signal using the double-beam technique when the sensor is used to monitor the Cr flux coming from an effusion cell held at 1410° C. For the first 16 minutes of the measurement, a closed shutter blocks the beam. The shutter is opened at 16 min and strong absorbance signals are observed for all resonant lines whereas little change is observed in the non-resonant line.

It is clear that A1 is the resonant line with the highest absorption coefficient and thus offers the best sensitivity. The resonant absorbance line preferred for monitoring can be the one with the highest absorption coefficient. When the shutter is closed at 24 min, the absorbance signals for A1, A2, and A3 all drop down to the level of A4, but all four lines display a non-zero reading. This baseline drift is spurious and detrimental for quantitative analysis and process control. As discussed earlier, because the non-resonant line present in the sampling spectra data originates from the same HCL and goes through the same optical path, it provides an ideal way to monitor and correct for baseline drift in real-time. In FIG. 3C, (A1-A4) is plotted to show absorbance vs. time based on embodiments described herein of a background-corrected double-beam configuration. The background-corrected absorbance (A1-A4) thus gives an accurate measure of Cr atom flux, replete with a shutter transient upon initial shutter opening, and returns to zero absorbance when the shutter is closed. It should be noted that if a non-resonant line is not readily available, a resonant line with a lower absorbance (i.e. a smaller AA cross section) can be used for background correction. For example, if (A1-A2) or (A1-A3) in FIG. 2(b) were plotted, the background correction would be very similar to that seen in FIG. 2(c). One disadvantage in using a resonant line for this purpose is that the signal-to-noise ratio will be lower as the magnitude of the absorbance is smaller. It should also be noted that if sufficient warm-up time is allowed (e.g, 60 min rather than 20 min), the baseline drift detected over a 30 min range can be further reduced, but not completely eliminated for the direct double-beam configuration (FIG. 3B). While drift is inherent in any AA measurement, embodiments described herein can surprisingly and effectively remove most of it without extensive and painstaking mechanical and thermal stabilization. Therefore, much shorter warm-up time is needed when using a non-resonant line for background-correction.

In many deposition processes, such as MBE, it is critically important to control individual fluxes at an extremely slow, reproducible, and known rates. Embodiments described herein can comprise a controller configured to regulate the rate of output of the atomic species according to the background-corrected absorbance values and/or deposition rates. The controller, the source and a computational device can be connected in a feedback and/or feedforward loop. The computational device can be configured to process the sampling and reference spectral data, analyze the absorption signals, and provide feedback control to the power supply via a PID algorithm, which can effectively regulate the atom flux. In one example, a feedback configuration comprises a PID loop wherein an AA sensor can supply a signal in order to regulate the power supply of an electron-beam or effusion cell evaporation source to maintain constant absorbance during evaporation of an atomic species. For small absorbance, the deposition rate on the substrate and the absorbance have a linear relationship. The deposition rate can be experimentally determined by placing a quartz crystal oscillator (QCO) at either the sample growth position, or alongside the sample manipulator. In the latter case, a tooling factor is applied to compensate for the difference in position between substrate and QCO sensor. For materials that grow in a controlled layer-by-layer fashion, it is also possible to accurately measure the deposition rate by monitoring the reflection high-energy electron diffraction (RHEED) intensity oscillations during MBE growth.

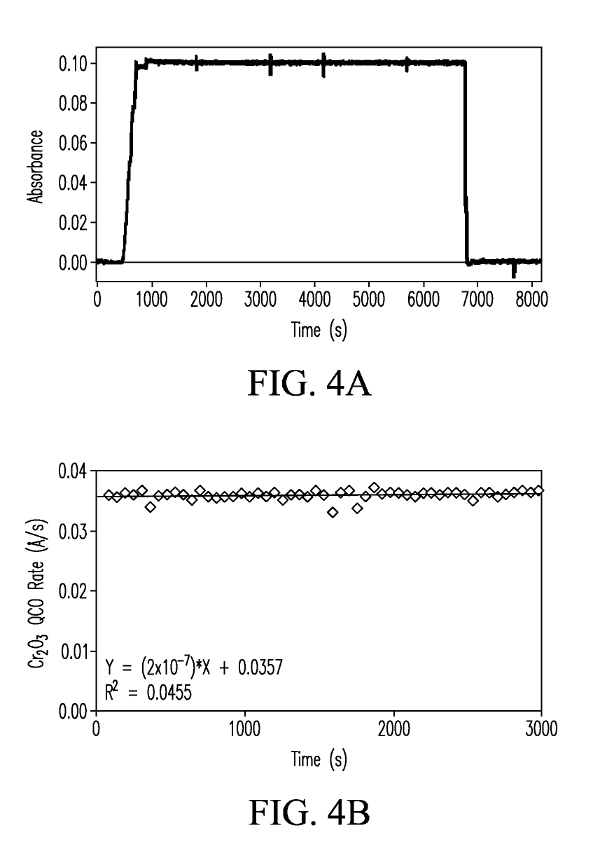

Utilizing both a QCO sensor and the RHEED intensity oscillations from epitaxial single crystalline α-Cr₂O₃/α-Al₂O₃(0001) film growth to provide a time-dependent rate comparison, the AA sensor was used to monitor and control the evaporation rate of Cr from an electron beam evaporator. During the 90 min of deposition, the α-Al₂O₃ substrate was heated to 500° C. and exposed to an oxygen plasma at a pressure of 1×10⁻⁵ Torr to facilitate complete oxidation of Cr atoms. FIG. 4A depicts an experimental trace for the atomic absorption controlled electron beam evaporation of Cr, revealing that the absorbance is maintained at 0.10. The QCO was programmed with the input parameters for Cr₂O₃ growth, but the rate shown is not accurate in an absolute sense because it is located off to the side and an accurate tooling factor was not pre-determined prior to deposition. In addition, considerable time (tens of minutes) is needed for a QCO sensor to reach thermal equilibrium and provide consistent readings once the source shutter is opened. Forty minutes were allowed for the QCO to reach thermal equilibrium and only the last 50 min of deposition were recorded to ensure thermal equilibrium. FIG. 4B shows the QCO rate measured after 40 min of deposition. The deposition rate was measured to be ˜0.0357 Å/sec at the beginning and 0.0363 Å/sec at the end of growth. The flux increased slightly over a 50 minute period by 0.0006 Å/sec (+1.7%), as determined from a linear least-squares fit shown as the line in FIG. 4B.

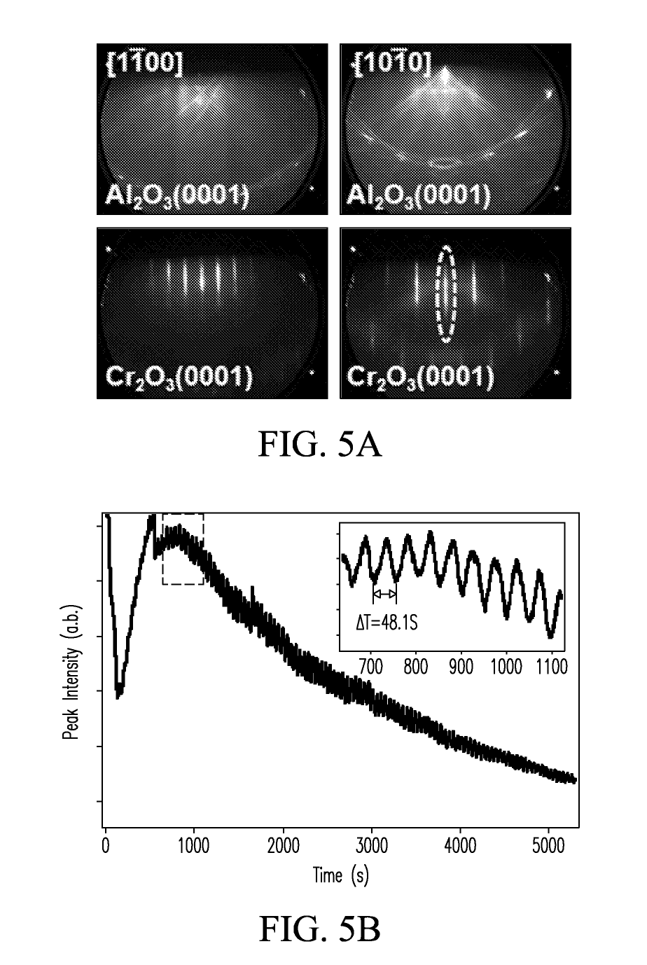

The associated RHEED patterns for the substrate, resultant Cr₂O₃ film, and specular spot intensity oscillation were recorded for the epitaxial film growth as they provide information on film quality, epitaxial orientation, and growth rate. FIG. 5A shows the RHEED patterns for the α-Al₂O₃(0001) substrate and the Cr₂O₃(0001) film along two different azimuthal directions. The sharp, streaky patterns for the resultant Cr₂O₃ film demonstrate the epitaxial orientation and excellent quality of the film. More importantly, the RHEED intensity oscillations (FIG. 5B) for the specular spot (dotted oval in FIG. 5A), reveal that the film grows in a layer-by-layer fashion. An average Cr₂O₃ growth rate can be determined from the period of oscillations (˜48 sec) along with the interlayer spacing for Cr₂O₃(0001) (˜2.3 Å). Reasonably strong oscillations appeared shortly after the deposition started and persisted throughout the deposition process (90 min). The expanded view shown in the inset for FIG. 5B reveals that the period is 48.1 sec (corresponding to a film growth rate of 0.0478 Å Cr₂O₃/sec) at the beginning. The period dropped to 47.4 sec by the end of growth. This change corresponds to a +1.5% increase in deposition rate, consistent with the QCO measurement. In 90 min, a total of 113 oscillations, corresponding to 113 ML, were observed, giving a total thickness of 26.0 nm. A QCO tooling factor of 1.34 (0.0478/0.0357) is needed to reconcile the rate determined from the RHEED oscillations with that from the QCO. This value is consistent with expectation that the rate as measured by the QCO will be lower than that at the substrate because the QCO is located ˜75 mm to the side of the sample during deposition. A very low growth rate can be held steady over the course of 90 min using embodiments described herein. This represents unprecedented sensing and control of the rate of output from the source of the atomic species, which is Cr in this case.

While a number of embodiments of the present invention have been shown and described, it will be apparent to those skilled in the art that many changes and modifications may be made without departing from the invention in its broader aspects. The appended claims, therefore, are intended to cover all such changes and modifications as they fall within the true spirit and scope of the invention.

We claim:

1. A system for controlling a deposition process by monitoring background-corrected deposition rates of an atomic species via atomic absorption (AA) spectroscopy, the system comprising:
A source of the atomic species configured to provide the atomic species into a volume at a rate of output;
A light source configured to emit light having at least one wavelength that is at least partially absorbed by the atomic species;
Optical guides configured to direct a portion of the light as a reference beam to a spectrometer and another portion of the light as an AA sampling beam through the volume and then to the spectrometer;
The spectrometer configured to spatially disperse according to wavelength the AA sampling beam emerging from the volume and the reference beam onto a two-dimensional detector, thereby yielding sampling spectral data and reference spectral data, respectively;
A computational device configured to receive the sampling spectral data and the reference spectral data from the detector and programmed to quantify a non-resonant absorbance value (A_{NR}) and a resonant absorbance value (A_{R}) from the sampling and reference spectral data, to correct the A_{R} value according to the A_{NR} value at common moments in time, thereby yielding background-corrected absorbance values, and to determine background-corrected deposition rates of the atomic species based on a correlation between the background-corrected absorbance values and the rates of output; and
a controller connected to the computational device in a feedback loop configuration, wherein the controller is configured to regulate the rate of output of the atomic species according to the background-corrected deposition rates.

2. The system of claim 1, wherein the source of the atomic species comprises an evaporator.

3. The system of claim 2, wherein the evaporator comprises an electron-beam evaporator or an effusion cell evaporator connected to a power source, and the controller comprises a PID controller connected to the power source, the PID controller regulating the power provided to the evaporator.

4. The system of claim 1, wherein the volume is at least a portion of a deposition chamber.

5. The system of claim 1, wherein the light source comprises a hollow cathode lamp.

6. The system of claim 1, wherein the detector comprises a two-dimensional charge-coupled device (CCD) camera.

7. The system of claim 1, further comprising additional optical guides directing the AA sampling beam and the reference beam to the detector, wherein the detector includes a first region and a second region on which the AA sampling beam and the reference beam impinge, respectively.

8. The system of claim 1, wherein the optical guides comprise an optical fiber bundle having a linear arrangement of fibers at an output end that is proximal to the spectrometer.

9. The system of claim 1, wherein the A_{R} value and the A_{NR} value have a wavelength separation of 0.5-30 nm.

10. A system for controlling a deposition process by monitoring background-corrected deposition rates of an atomic species via atomic absorption (AA) spectroscopy, the system comprising:
An evaporator comprising a source of the atomic species and providing the atomic species into a deposition chamber at a rate of output;
A hollow cathode lamp (HCL) configured to emit light having at least one wavelength that is at least partially absorbed by the atomic species;
One or more optical fiber bundles configured to direct a portion of the light as a reference beam to a spectrometer and another portion of the light as an AA sampling beam through the deposition chamber and then to the spectrometer, the optical fiber bundle having a linear arrangement of optical fibers at an output end that is proximal to the spectrometer;
The spectrometer configured to spatially disperse according to wavelength the AA sampling beam emerging from the deposition chamber and the reference beam onto a two-dimensional detector having a first region and a second region, the AA sampling beam and reference beam directed by optical guides to impinge the first and second regions, respectively, thereby yielding sampling spectral data and reference spectral data, respectively;
A computational device configured to receive the sampling spectral data and the reference spectral data from the detector and programmed to quantify a non-resonant absorbance value (A_{NR}) and a resonant absorbance value (A_{R}) from the sampling and reference spectral data, to correct the A_{R} value according to the A_{NR} value at common moments in time, thereby yielding background-corrected absorbance values, and to determine background-corrected deposition rates of the atomic species based on a correlation between the background-corrected absorbance values and the rates of output; and
a controller connected to the computational device in a feedback loop configuration, wherein the controller is configured to regulate the rate of output of the atomic species according to the background-corrected deposition rates.

11. The system of claim 10, wherein the evaporator comprises an electron-beam evaporator or an effusion cell evaporator connected to a power source and the PID controller is connected to the power source, the PID controller regulating the power provided to the evaporator.

12. The system of claim 10, wherein the two-dimensional detector comprises a CCD camera.

13. The system of claim 10, wherein the A_{R} value and the A_{NR} value have a wavelength separation of 0.5-30 nm.

14. A method for controlling a deposition process by monitoring background-corrected deposition rates of an atomic species via atomic absorption (AA) spectroscopy, the method comprising:
Emitting from a light source light having at least one wavelength that is at least partially absorbed by the atomic species;
Directing a portion of the light as a reference beam to a spectrometer and another portion of the light as an AA sampling beam through a volume containing the atomic species and then to the spectrometer;
Spatially dispersing according to wavelength the AA sampling beam emerging from the volume and the reference beam onto a two-dimensional detector, thereby yielding sampling spectral data and reference spectral data, respectively;
Quantifying by a computational device a non-resonant absorbance value (A_{NR}) and a resonant absorbance value (A_{R}) from the sampling and reference spectral data;
Correcting the A_{R} values according to the A_{NR} values at common moments in time, thereby yielding background-corrected absorbance values;
Determining background-corrected deposition rates of the atomic species based on a correlation between a rate of output of the atomic species and the background-corrected absorbance values.
Regulating the rate of output of the atomic species using a controller according to the background-corrected deposition rates, wherein the controller is connected to the computational device in a feedback configuration.

15. The method of claim 12, further comprising providing the atomic species by heating an evaporator via an electron-beam evaporator or an effusion cell evaporator connected to a power source and regulating the power source using a controller connected to the power source.

16. The method of claim 12, wherein the two-dimensional detector comprises a two-dimensional CCD camera.

17. The method of claim 12, further comprising directing the AA sampling beam from the spectrometer to a first region of the two-dimensional detector and directing the reference beam from the spectrometer to a second region of the two-dimensional detector.

18. The method of claim 12, wherein the optical guides comprise an optical fiber bundle having a linear arrangement of fibers at an output end that is proximal to the spectrometer.

19. The method of claim 12, wherein the A_{R} value and the A_{NR} value have a wavelength separation of 0.5-30 nm.
